(19) United States
(12) Patent Application Publication
(10) Pub. No.: US 2010/0213166 A1
(43) Pub. Date: Aug. 26, 2010

(54) Process and Device for The Precision-Processing Of Substrates by Means of a Laser Coupled Into a Liquid Stream, And Use of Same

(75) Inventors: Daniel Kray, Freiburg (DE); Ansgar Mette, Leipzig (DE); Daniel Biro, Freiburg (DE); Kuno Mayer, Freiburg (DE); Sybille Hopman, Mahlberg (DE); Stefan Reber, Gundelfingen (DE)

Correspondence Address: GIBSON & DERNIER LLP, 900 ROUTE 9 NORTH, SUITE 504, WOODBRIDGE, NJ, 07095, US

(73) Assignees: FRAUNHOFER-GESELLSCHAFT ZUR FÖRDERUNG DER ANGEWANDTEN FORSCHUNG E.V., Münich (DE); ALBERT-LUDWIGS-UNIVERSITAT FREIBURG, Freiburg (DE)

(21) Appl. No.: 12/161,025

(22) PCT Filed: Jan. 25, 2007
(86) PCT No.: PCT/EP2007/000639

§ 371 Date: Feb. 2, 2009

(30) Foreign Application Priority Data
Jan. 25, 2006 (DE) 10 2006 003 606.9
Jan. 25, 2006 (DE) 10 2006 003 607.7

(51) Int. Cl. C23F 1/00; C23C 14/14; C25D 5/22; C25D 5/34

(52) U.S. Cl. 216/37; 427/596; 427/597; 205/92; 118/620

(57) ABSTRACT

The invention relates to a method for precision processing of substrates in which a liquid jet which is directed towards a substrate surface and contains a processing reagent is guided over the regions of the substrate to be processed, a laser beam being coupled into the liquid jet. Likewise, a device which is suitable for implementation of the method is described. The method is used for different process steps in the production of solar cells.

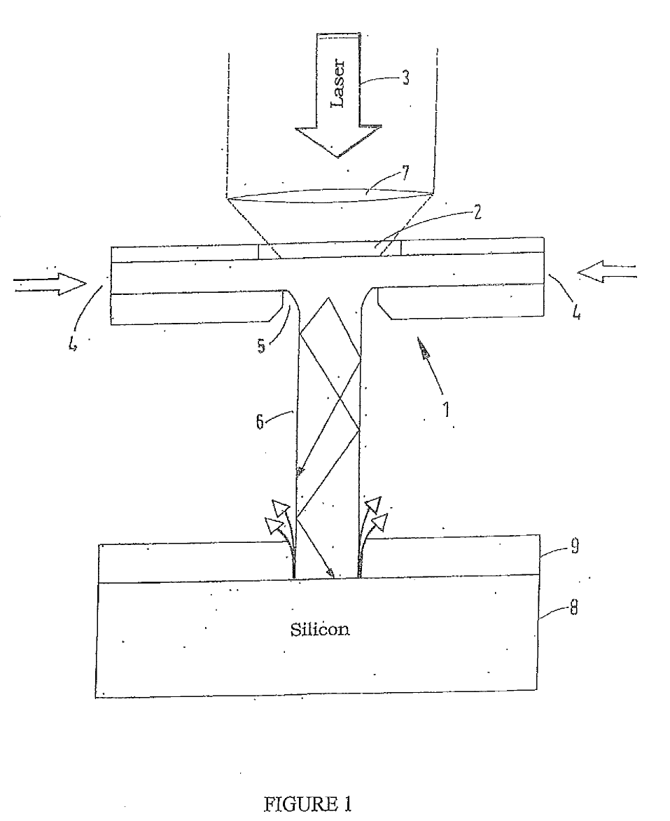

The invention relates to a method for precision processing of substrates in which a liquid jet which is directed towards a substrate surface and comprises a processing reagent is guided over the regions of the substrate to be processed, a laser beam being coupled into the liquid jet. Likewise, a device which is suitable for implementation of the method is described. The method is used for different process steps in the production of solar cells.

The production of solar cells involves a large number of process steps for precision processing of wafers. There are included herein inter alia emitter diffusion, the application of a dielectric layer and also the microstructuring thereof, the doping of the wafer, the contacting, the application of a nucleation layer and also thickening thereof.

With respect to the microstructuring for the front-side contacting, the microstructuring of thin silicon nitride layers (SiNₓ) is the application which is current at present. Such layers form at present the standard antireflection coating in commercial solar cells. Since this antireflection coating, which serves also in part as front-side passivation of the solar cell, is applied before the front-side metallisation, this non-conductive layer must be opened directly on the silicon substrate by corresponding microstructuring locally for application of the metal contacts.

The printing of SiNₓ layers with a glass frit-containing metal paste is hereby state of the art. This is firstly dried, the organic solvent being expelled and then being fired at high temperatures (approx. 900° C.). The glass frit thereby attacks the SiNₓ layer, dissolves it locally and consequently enables the formation of a silicon-metal contact. The high contact resistance which is caused by the glass frit (>10⁻³ Ωcm²) and the required high process temperatures which can reduce both the quality of the passivation layers and that of the silicon substrate are disadvantageous in this method.

A previously known gentle possibility for opening the SiNₓ layer locally resides in the application of photolithography combined with wet chemical etching methods. Firstly a photoresist layer is thereby applied on the wafer and this is structured via UV exposure and development. A wet chemical etching step follows in a hydrofluoric acid-containing or phosphoric acid-containing chemical system which removes the SiNₓ at the positions at which the photoresist was opened. A great disadvantage of this method is the enormous complexity and the costs associated therewith. In addition, with this method, a throughput which is adequate for solar cell production cannot be achieved. In the case of some nitrides, the method described here cannot be applied in addition since the etching rates are too low.

In addition, it is known from the state of the art to remove a passivation layer comprising SiNₓ with the help of a laser beam by means of purely thermal ablation (dry laser ablation).

With respect to the doping of the wafers, local doping by means of photolithographic structuring of a grown SiO₂ mask with subsequent whole-surface diffusion in a diffusion oven is state of the art in microelectronics. The metallisation is achieved by vapour deposition on a photolithographically defined lacquer mask with subsequent dissolving of the lacquer in organic solvents. This method has the disadvantage of very great complexity, high time and cost requirement and also whole-surface heating of the component which can change possibly further diffusion layers which are present and also can impair the electronic quality of the substrate.

Local doping can be effected also via screen printing of a self-doping (e.g. aluminium-containing) metal paste with subsequent drying and firing at temperatures about 900° C. The disadvantage of this method is the high mechanical stressing of the component, the expensive consumed materials and also the high temperatures to which the entire component is subjected. Furthermore, only structural widths>100 μm are herewith possible.

A further method (“buried base contacts”) uses a whole-surface SiNₓ layer, opens this locally by means of laser radiation and then diffuses the doping layer in the diffusion oven. By means of the SiNₓ masking, a highly doped zone is formed only in the laser-opened regions. The metallisation is formed after back-etching of the resulting phosphosilicate glass (PSG) by means of currentless deposition in a metal-containing liquid. The disadvantage of this method is the damage introduced by the laser and also the necessary etching step for removing the PSG. In addition, the method comprises several separate steps which make many handling steps necessary.

Starting herefrom, it was the object of the present invention to facilitate technical process implementation of the individual method steps for precision processing of substrates, in particular wafers, and to enable, at the same time, higher precision of these process steps.

This object is achieved by the method having the features of claim 1 and also by the device having the features of claim 51. The further dependent claims reveal advantageous developments. Uses according to the invention are cited in claims 54 to 57.

According to the invention, a method is provided for precision processing of substrates in which a liquid jet which is directed towards a substrate surface and comprises a processing reagent is guided over the regions of the substrate to be processed. An essential feature of the method according to the invention is thereby that a laser beam is coupled into the liquid jet.

The method according to the invention uses a technical system in which a liquid jet, which can be fitted with various chemical systems, serves as liquid light guide for a laser beam. The laser beam is coupled via a special coupling device into the liquid jet and is guided by means of internal total reflection. In this way, a temporally and locally identical supply of chemicals and laser beam to the process hearth is guaranteed. The laser light thereby undertakes various tasks: on the one hand, it is able to heat the substrate surface locally at the impingement point thereon, optionally thereby to melt it and in the extreme case to evaporate it. As a result of the simultaneous impingement of chemicals on the heated substrate surface, chemical processes can be activated which do not take place under standard conditions because they are kinetically inhibited or thermodynamically unfavourable. In addition to the thermal effect of the laser light, photochemical activation is also possible in that the laser light on the surface of the substrate generates for example electron pairs of holes which can promote or even make at all possible the course of redox reactions in this region.

The liquid jet, in addition to focusing of the laser beam and the chemical supply, also ensures cooling of the edge-situated regions of the process hearth and rapid transport away of the reaction products. The last-mentioned aspect is an important prerequisite for the promotion and acceleration of rapidly occurring chemical (equilibrium) processes. Cooling of the edge-situated regions which are not involved in the reaction and, above all, are not subjected to the material removal, can be protected by the cooling effect of the jet from thermal tensions and crystalline damage resulting therefrom, which enables a low-damage or damage-free structuring of the solar cells. Furthermore, the liquid jet endows the supplied materials with a significant mechanical impulse due to its high flow rate, said impulse being particularly effective when the jet strikes a molten substrate surface.

Laser beam and liquid jet together form a new process tool which, in its combination, is in principle superior to the individual systems which it comprises.

All the chemical processes which take place during microstructuring, doping or metallisation of silicon solar cells take place at increased temperatures. This implies conversely that the chemicals required for this purpose do not react or only very poorly under standard conditions.

SiNₓ, which is used predominantly as antireflection layer on silicon solar cells, can itself be etched at very high temperatures for liquids (above 150° C.) only with very low etching rates of merely a few 100 nm to a few μm per hour. The attacking etching particle is generally the proton which can originate from various acids; however, because of the high temperatures required for the etching process, concentrated phosphoric acid is used, the boiling point of which is approx. 180° C., as a result of which it has the highest boiling point amongst all current, commercially conveniently available, technical acids. The etching reaction takes place according to the diagram:

3Si₃N₄+27H₂O+4H₃PO₄→4(NH₄)₃PO₄+H₂SiO₃

Standard nickel-electroplating baths operate from temperatures of at least 70° C., but mostly—according to the composition—are effective only from 90-100° C.

The formation of the phosphosilicate glass consisting of phosphoryl chloride, POCl₃, or phosphoric acid with subsequent phosphorus diffusion is effected at temperatures above 800° C.

The substrate is preferably selected from the group consisting of silicon, glass, metal, ceramic, plastic material and composite materials thereof. The substrate can thereby also have preferably one or more coatings on the surface to be treated. There are included herein coatings consisting of SiNₓ, SiO₂, SiOₓ, MgF₂, TiO₂ or SiCₓ.

A liquid jet which is as laminar as possible is used preferably for implementation of the method. The laser beam can be guided then, in a particularly effective manner, by total reflection in the liquid jet so that the latter fulfils the function of a light guide. Coupling of the laser beam can be effected for example by means of a window which is orientated perpendicular to a jet direction of the liquid jet in a nozzle unit. The window can thereby be configured also as a lens for focusing the laser beam. Alternatively or additionally, a lens which is independent of the window can also be used to focus or form the laser beam. The nozzle unit can thereby be designed in a particularly simple embodiment of the invention such that the liquid is supplied from one side or from a plurality of sides in a radial direction relative to the jet direction.

There are preferred as usable types of laser:

Various solid lasers, in particular the commercially frequently used Nd:YAG laser of wavelength 1064 nm, 532 nm, 355 nm, 266 nm and 213 nm, diode lasers with wavelengths<1000 nm, argon-ion lasers of wavelength 514 to 458 nm and Excimer lasers (wavelengths: 157 to 351 nm).

The tendency is for the quality of the microstructuring to increase with a reducing wavelength because the energy induced by the laser in the surface layer is thereby increasingly concentrated better and better on the surface, which has a tendency to lead to the reduction in the heat influence zone and, associated therewith, to reduction in the crystalline damage in the material, above all in the phosphorus-doped silicon below the passivation layer.

Blue lasers and lasers in the near UV range (e.g. 355 nm) with pulse lengths in the femtosecond to nanosecond range prove to be particularly effective in this context. By using in particular shortwave laser light, the option exists in addition for a direct generation of electron/pairs of holes in the silicon which can be used for the electrochemical process during the nickel deposition (photochemical activation). Thus, free electrons which are generated for example by laser light in the silicon can in addition contribute to the above already-described redox process of the nickel-ions with phosphorous acid directly to reduction of nickel on the surface. This electron/hole generation can be maintained permanently by permanent illumination of the sample at defined wavelengths (in particular in the near UV with λ355 nm) during the structuring process and can promote the metal nucleation process in a sustained manner.

For this purpose, the solar cell property can be exploited in order to separate the excess charge carriers via the p-n junction and hence to charge the n-conductive surface negatively.

A further preferred variant of the method according to the invention provides that the laser beam is actively adjusted in temporal and/or spatial pulse form. The flat top form, an M-profile or rectangular pulse are included herein.

The precision processing according to the invention, in a first preferred variant, can comprise an emitter diffusion of a doping agent into a silicon wafer as substrate.

As a result of the local heating of the substrate by the laser beam, the temperatures required for the diffusion in the substrate and the doping agent can be confined within this limited region. Since the diffusion is effected only extremely slowly at low temperatures, doping of the substrate is hence achieved only in the region of the impinging laser radiation whilst, in the adjacent regions of the substrate, no change is produced.

As a result of the method according to the invention, crystal damage with local doping is avoided since, by means of the laser radiation, the surface temperature can be kept below the melting point. Furthermore, temperature stressing of the entire substrate is avoided.

With respect to the doping agents comprised in the liquid jet, all doping agents known from the state of the art can be used. For particular preference, doping agents are selected here from the group consisting of phosphorus, boron, indium, gallium and mixtures hereof.

A further preferred variant provides that, before or after one of the steps for precision processing of the substrate, a dielectric layer is deposited on the substrate. This layer serves for the passivation of the surface of the substrate.

The dielectric layer is thereby preferably selected from the group consisting of SiNₓ, SiO₂, SiOₓ, MgF₂, TiO₂ and SiCₓ.

A further preferred variant of the method according to the invention provides that microstructuring of the previously described dielectric layer is effected during the precision processing.

The microstructuring is based on opening of the dielectric layer which is opened preferably by treatment with a dry laser or a water jet-guided laser or a liquid jet-guided laser which contains an etching agent.

It is thereby preferred that the dielectric layer is opened by treatment with the liquid jet-guided laser which contains the processing reagent and the processing reagent is an etching agent which has a more strongly etching effect on the dielectric layer than on the substrate. An etching agent is thereby preferably selected as processing reagent with which damage in the substrate can also be re-etched. Preferred etching agents are selected from the group consisting of phosphorus-containing acids, e.g. H₃PO₄ and H₃PO₃, KOH, HF/HNO₃, chlorine compounds and sulphuric acid.

The liquid jet can be formed particularly preferably from pure or highly concentrated phosphoric acid or even diluted phosphoric acid. The phosphoric acid can be diluted for example in water or in another suitable solvent and used in a different concentration. Also additions for changing the pH value (acids or caustic soda solutions), wetting behaviour (e.g. surfactants) or viscosity (e.g. alcohols) can be added. Particularly good results are achieved when using a liquid which contains phosphoric acid with a proportion of 50 to 85% by weight. Hence in particular rapid processing of the surface layer can be achieved without damaging the substrate and surrounding regions.

By means of the microstructuring according to the invention, two different things are achieved with very low complexity.

On the one hand, the surface layer can be removed in the mentioned regions completely without the substrate thereby being damaged because the liquid on the latter has a less (preferably absolutely no) etching effect. At the same time, by means of local heating of the surface layer in the regions to be removed, as a result of which preferably these regions are heated exclusively, a well localised removal of the surface layer which is restricted to these regions is made possible. This results from the fact that the etching effect of the liquid increases typically with increasing temperature so that damage to the surface layer in adjacent, non-heated regions by parts of the etching liquid possibly passing thereto is extensively avoided.

In order to achieve as advantageous as possible a metal contacting with as low as possible contact resistance, the liquid jet in the present invention, during microstructuring, has in addition to the etching liquid in liquid form a reduction agent and optionally in addition a metal salt. Advantageously, the etching agent and the reduction agent thereby have one and the same chemical element, e.g. phosphorus, in different oxidation states. In particularly advantageous embodiments, the following pairs are hence used in the component system; as etching liquid H₃PO₄ and, as reduction agent, H₃PO₃; as etching liquid H₂SO₄ and, as reduction agent, H₂SO₃; as etching liquid HNO₃ and, as reduction agent, HNO₂. Advantageously, additions of KF ensure a defined quantity of free hydrofluoric acid which increases the etching rate on the SiN even more. There may be used particularly advantageously as metal salt salts of silver, of nickel, of tin, of Pb, of aluminium or of chromium. With the help of the reduction agent, a higher doping of the emitter layer or substrate layer with respect to the doping concentration is possible, which improves a subsequent, for example galvanic, metal deposition and reduces the contact resistance. When adding a metal salt, with the help of the reduction agent at the heated local surface regions, a reduction in metal ions into elementary metal is possible, which leads to the formation of effective deposition nuclei for a subsequent electroplating process. Such a deposition of metal particles hence likewise leads to a metal contact with a low contact resistance being able to be formed.

As a result of the metal contactings improved in such a manner, the conductivity of solar cells produced in this way is improved without an increased processing complexity resulting.

In the case of typical applications of the microstructuring according to the invention, the surface layer will have a thickness of between 1 nm and 300 nm. The substrate can have a layer thickness of between 25 μm and 800 μm in typical applications of the method. Hence, a construction which is suitable for example for the production of solar cells would be produced.

Relative to the microstructuring processes known from the state of the art, the following aspects of the present invention can be regarded as advantageous developments:
1) The liquid jet-guided laser method is mask-free, i.e. application and removal of a masking layer is not required.
2) The removal of coatings or substrate material is effected free of damage, i.e. subsequent cleaning or re-etching is not required.

Relative to the pure, dry laser ablation of the state of the art in the field of microstructuring, the method according to the invention has the following advantages:
The material removal from the surface layer is effected here more cleanly than in the case of dry, purely thermal ablation because evaporated or molten material there, which has a very high melting or boiling point, is deposited again to a certain extent on the colder edges of the processed region. The use of etching chemicals reduces or entirely prevents this undesired redeposition in that the removed material is transferred into a form, e.g. gaseous or readily soluble products, which can be transported away easily from the removal hearth.
The liquid jet-guided laser exploits the cooling effect of the liquid jet in order to minimise the heat influence zone around the processing region and hence to reduce thermal damage in the substrate.
Liquid jet-guided lasers have a larger operating range with respect to the spacing between laser source and substrate. This is based essentially on the following aspect: conventional laser beams are conical, i.e. they have a focal point. The operating spacing is restricted to strict limits around this focal point since, in it, the laser beam has the highest intensity and the smallest spot. Liquid jet-guided laser beams, on the other hand are focused until the liquid light guide or liquid jet maintains its laminarity. This is normally the case over stretches of several centimetres. Refocusing, as is required with conventional dry lasers, above all if deeper grooves are intended to be produced, is superfluous here.

Relative to photogalvanic methods with conventional dry laser systems and standing etching solutions, the microstructuring according to the invention with a liquid jet-guided laser has the following advantages:
If a “dry” laser beam is focused through a liquid layer which is situated on the substrate and covers the latter, then significant quantities of the laser light are scattered in the liquid layer, which represents, on the one hand, a significant loss of power and, on the other hand, significantly restricts the focusability of the laser spot. Such a scatter is avoided with a liquid jet-guided laser. In fact after radiation by the liquid, a liquid film is also formed here over the substrate surface (as a result of the discharging liquid from the etching hearth) but the latter is displaced practically entirely by the high impulse of the liquid jet and therefore plays no role as scatter medium for the laser light.
Due to the high flow rates at the reaction site, the forming etching products are rapidly transported away. This fact is of considerable importance with many chemical processes, the reaction speeds of which are subject to a diffusion control since it consequently increases the reaction rate thereof. In the case of conventional laser systems, solely due to the temperature gradient between heated substrate surface and the colder solution situated thereabove, convection currents are produced in contrast (“micro-stirring”), which produce substantially less vigorous mixing of the solution than the liquid jet.
Furthermore, the liquid jet enables in addition cleaning of the substrate surface of impurities due to foreign materials, e.g. suspended matter from the air, which are physically adsorbed on the surface.

A particularly preferred variant provides that the microstructuring and the doping are implemented simultaneously. A further variant according to the invention involves doping of the microstructured silicon wafer being effected subsequent to the microstructuring during the precision processing and the processing reagent containing a doping agent.

This can be achieved in that, instead of the liquid which contains at least one doping agent, a liquid which contains at least one compound which etches the solid material is used. This variant is particularly preferred since, in the same device, firstly the microstructuring and, by means of exchange of liquids, subsequently the doping can be implemented. Alternatively, the microstructuring can also be implemented by means of an aerosol jet, laser radiation not being absolutely necessary in this variant since comparable results can be achieved in that the aerosol or the components thereof are preheated.

The method according to the invention likewise comprises, as further variant, that, during the precision processing, doping is produced only in regions in the substrate, subsequently liquid situated on the substrate surface is dried up and the substrate is treated thermally so that the substrate has a weak surface doping and a confined high local doping.

The doping agent which is used is preferably selected from the group consisting of phosphoric acid, phosphorous acid, POCl₃, PCl₃, PCl₅, boron compounds, gallium compounds and mixtures hereof.

Relative to the doping processes known from the state of the art, the following aspects of the present invention can be regarded as advantageous developments:
1) The method to be patented here requires no application of the phosphorus source on the surface to be doped before the actual doping step, for instance by means of preceding coating of the substrate surface with a phosphorus glass. Phosphorus source supply and diffusion can be undertaken at the same time in a one-step process.
2) During doping with the new method no further temperature-control step is absolutely necessary.
3) With relatively low technical complexity in comparison with previous methods, very high doping concentrations (approx. 10²¹ P-atoms/cm³) and, associated therewith, low contact resistances are achieved.

According to a further variant of the method according to the invention, the precision processing comprises application of a nucleation layer on a silicon wafer at least in regions. This hereby involves therefore a metallisation step.

It is thereby preferred that, subsequent to the doping, a metallisation of the doped surface regions is implemented by exchange of the liquid which contains the doping agent for a liquid which contains at least one metal compound. Here too, it is again particularly simple to implement the method steps of doping and metallisation sequentially in the same device by means of changing the corresponding liquids.

The application can thereby be effected by nickel electroplating, nickel laser methods, ink jet methods, aerosol methods, vapour coating, laser microsintering, screen printing and/or tampon printing. It is hereby particularly preferred that the application of the nucleation layer is implemented with the liquid jet-guided laser which contains the processing reagent, the processing reagent comprising at least one metal compound.

Preferably, a compound is used as metal compound during metallisation from the group of metals consisting of silver, aluminium, nickel, titanium, molybdenum, tungsten and chromium. For particular preference, silver cyanide or silver acetate and solutions thereof is used as metal compound.

If a laser beam is used during application of the nucleation layer, then the latter can catalyse the metallisation in the region of the impingement point of the liquid jet on the surface. The metallisation can thereby be continued until the desired total thickness is achieved or else is stopped after growth of a thin layer of a few nanometres and subsequently is thickened galvanically.

The just described variant enables a complete method in which e.g. a silicon wafer can be structured, doped and metallised in a single processing station merely by exchanging the liquids which are used.

Preferably, the nucleation layer is applied on the doped regions of the silicon wafer.

Relative to the metallisation methods known from the state of the art, the following aspects can be regarded above all as advantageous developments of previous processes:
1) With the new method, both opening of the nitride layers, doping and nucleation or coating of the highly doped regions can be performed simultaneously in one single process step. Above all, the doping which takes place simultaneously with structuring of the nitride with one and the same technical device, represents an advantageous development relative to the previous BC solar cell contacting process.
2) By skilful choice of the doping/metallising solution, a damage etch of the manufactured grooves which runs in parallel with the doping/metallising can even be undertaken. As was shown already by Baumann et al. (2006), the LCE method enables damage-free removal of silicon material in one step without a further subsequent damage etch. Use is made of this advantage in the present invention.
3) As a result of the special mechanism during the contacting, the contact qualities can be improved, which are expressed, on the one hand, in improved adhesion and, on the other hand, in a reduction in contact resistance, due to nickel silicide formation on the contact surfaces, as a result of which a further sintering process is no longer absolutely necessary even at this point of the process.
4) Likewise, the apparatus which is used saves additional heating of the doping/metallising solutions.

A further preferred variant provides that the steps for precision processing of the substrate comprise microstructuring, doping and application of the nucleation layer, these individual steps being able to be implemented in succession or in parallel.

The reagents used during these process steps have significant chemical parallels: in all three process steps, phosphorus-containing substances are used but sometimes with different oxidation states of the phosphorus. The latter has the oxidation state +V in phosphoric acid whilst, in hypophosphite, it has the oxidation number +I and is there correspondingly a strong reduction agent whilst the hydrogen phosphate ion shows neither a strong reduction tendency nor oxidation tendency. The reduction tendency of the hypophosphite is a function of the pH value of the solution; in basic solutions, it is higher than in the neutral or acidic medium. In contrast, the etching effect of phosphoric acid on the silicon nitride is only shown to advantage in acidic solutions. In the case of the phosphosilicate glass formation, the pH value of the phosphorus-containing substance which is used is of less importance than the saturation of the valencies of the phosphorus with oxygen atoms. These are required for network formation in the phosphosilicate glass where they form the bond bridges between the silicon- and phosphorus atoms. Correspondingly, phosphoric acid is a better glass former than for example phosphorous acid or hypophosphite. The vitrification of the low-oxygen phosphoryl chloride is effected for this reason only in an atmosphere which contains oxygen.

The composition of the individual reaction media, the chemistry of the phosphorus and its oxygen compounds and also the fact that, in the case of all three process steps, increased up to sometimes very high temperatures are required, enables combination of the three process steps: nitride structuring, phosphorus doping and metallisation of silicon solar cells in a single high-temperature step.

In a further preferred variant of the method according to the invention, a rear-side contacting is applied after application of the nucleation layer. This can be effected particularly preferably by vapour coating or sputtering of one or more metal layers (e.g. aluminium, silver or nickel). It is likewise possible that, after application of the nucleation layer, an additional rear-side contacting is applied by laser-fired rear-side contacting (LFC).

A further preferred variant provides that, after application of the nucleation layer, a thermal treatment, in particular at temperatures of 100° C. to 900° C., is effected for 0.5 to 30 min. This thermal treatment can be effected for example by laser annealing with point or line focus.

In a further precision processing according to the invention, thickening of the nucleation layer can be effected subsequent to application of the nucleation layer. This thickening is effected preferably by galvanic deposition, e.g. of Ag, or by currentless deposition, e.g. of Cu.

It is particularly preferred to provide a complete process for production of solar cells in which a plurality or all the previously mentioned methods steps are implemented in succession or in parallel. Hence, a complete process is possible in which microstructuring, doping, the application of a nucleation layer and the thickening of the nucleation layer are effected.

A device for implementation of a method of the described type can be configured such that it comprises a nozzle unit with a window for coupling of a laser beam, a liquid supply and a nozzle opening, the nozzle unit being retained by a guide device for controlled, preferably automated, guidance of the nozzle unit over the surface layer to be structured. In addition, the device typically comprises also a laser beam source with a light emergence surface which is disposed correspondingly to the window and can be provided for example by one end of a light guide. Alternatively or additionally, a device for implementation of a method according to the invention can comprise a nozzle for producing the liquid jet and a laser light source, the nozzle and the laser light source being retained by respectively one guide device or by one common guide device for guiding the nozzle and the laser light source over the same regions of the surface layer to be structured.

The method according to the invention is suitable in particular for different method steps in the process chain for the production of solar cells. There are associated herewith emitter diffusion of silicon wafers just as microstructuring of substrates, doping thereof and the application of nucleation layers on silicon wafers.

The subject according to the invention is intended to be explained in more detail with reference to the subsequent Figure and examples without wishing to restrict the latter to the special embodiments shown here.

The Figure shows a representation of a method according to the invention with a section through a substrate provided with a surface layer and a device according to the invention.

In the Figure, a nozzle unit 1 is represented which comprises a window 2 for coupling a laser beam 3 and also a liquid supply 4 and a nozzle opening 5. This nozzle unit serves to produce a liquid jet 6 in which the coupled laser beam is guided by total reflection. The window 2 is orientated perpendicular to a jet direction of the liquid jet 6. A precisely orientated lens 7 which is disposed above the window 2 serves to focus the laser beam 3. The component system which forms the liquid jet 6 (which is described subsequently in more detail) is supplied in a radial direction relative to the jet direction of the jet 6 at a pressure of 20 bar to 500 bar by the liquid supply 4 of the nozzle unit 1. The component system or individual components of the same are supplied to the liquid supply 4 from at least one storage container (not shown). The storage container or containers are thereby heatable so that the component system or the components thereof can be preheated before the supply to the liquid supply 4. The liquid jet 6 which is produced has a diameter of approx. 25 to 80 μm.

Likewise represented is a substrate 8 made of silicon with a layer thickness of 270 μm on which a surface layer 9 made of silicon nitride (SiNₓ) is disposed, which has a layer thickness of 70 nm. In the case of the method represented in the Figure, the surface layer 9 is microstructured in that the liquid jet 6 is guided with the laser beam 3 which is guided in this liquid jet 6 over regions of the surface layer to be removed. For this purpose, the nozzle unit 1 is retained by a guide device, not illustrated in the Figure, which guides the nozzle unit in a controlled manner over the surface layer 9 to be structured. As a result of the fact that the phosphoric acid and phosphorous acid which are contained here in the liquid jet 6 have an essentially stronger etching effect on silicon nitride than on silicon (etching taking place again almost exclusively wherever the surface layer 9 is heated), the surface layer 9 is removed very cleanly precisely wherever the liquid jet 6 is guided along, whilst the substrate 8 remains practically undamaged. Local heating of regions of the surface layer 9 to be removed is thereby effected by the laser beam 3 which is guided in the liquid jet 6. If the acids also touch adjacent regions of the surface layer 9 for example when being transported away, almost no damage is left there because those regions are not heated. In order to allow precise structuring of the surface layer 9, the nozzle unit 1 is designed such that the liquid jet 6 is laminar. In a not-represented final operating step (subsequent electroplating, here Ni electroplating), finally a metal layer is applied on the surface layer after the surface layer 9 has been opened locally in the portrayed manner. A solar cell is produced in the present case by the portrayed method.

The laser jet 3 is guided by internal total reflection in the liquid jet 6 which has a diameter of ≦100 μm. At the impingement point of the acid jet, the laser beam 3 also impinges and heats the SiNₓ of the layer 9 locally. Hence, at this point, the temperatures required for the wet chemical etching can be produced and the SiNₓ can be removed. Since H₃PO₄ and H₃PO₃ in the cold state etch SiNₓ only extremely slowly, a substantial removal is achieved merely in the region of the laser radiation and, in the adjacent regions of the SiNₓ layer, no change is produced. Since the acids in addition etch silicon considerably more slowly than SiNₓ, it can be ensured in a simple manner that only the SiNₓ layer and not the silicon situated thereunder is removed. Hence, the thin emitter layer which normally abuts against the SiNₓ and is only a few hundred nanometres is protected.

The use of a 3-component system with etching liquid, reduction agent and metal salt in the present invention is however not absolutely necessary. Thus, in a further embodiment according to the Figure, also merely a 2-component system can be used without metal salt (here without nickel salt). Hence, a mixture of phosphoric acid and phosphorous acid is used. The mentioned acid mixture or at least one of the two acids (phosphoric acid and phosphorous acid) is hereby preheated in a storage tank, not shown, and then is fired in hot form towards the nitride-coated surface 9 as a liquid jet 6 together with the laser beam 3. The nitride layer 9 is hereby removed in a combined process comprising ablation and etching. The phosphoric acid which is heated by the preheating is able to etch the silicon nitride 9 (but not the cold acid). The danger of undesired side etching however also does not arise here despite the additional preheating since the liquid jet 6, because of the small liquid quantities which are applied relative to the large cold surface of the nitride layer 9, via which the liquid jet 6 is atomised after impingement thereof, is cooled very rapidly on this surface.

In a third embodiment (not shown in the Figure), the use of the laser as removal instrument is entirely dispensed with in the present invention. In one embodiment of this type, the two- or three-component acid mixture alone in the laminar liquid jet 6 can be fired onto the nitride surface 9. The component mixture in the front area is hereby heated in at least one storage tank to approx. 20° C. below the boiling point of the component mixture. Such a limited heating avoids the formation of boiling bubbles in the liquid jet 6. In this embodiment, the nitride removal in the layer 9 is then restricted solely to the etch removal. By way of assistance, also the silicon wafer itself can hereby be heated to several 100° C. in order to accelerate the etching process.

In all the above-described cases, by using the component system according to the invention, the result is formation of a phosphorus glass layer, which is only a few monolayers thick, on the exposed surface portions of the substrate layer 8. This phosphorus glass layer has the advantage that as a result the emitter layer 8 which is doped in any case with phosphorus is doped at points more highly with phosphorus, which improves the subsequent galvanic nickel deposition and reduces the contact resistance according to the invention. In this context, the phosphorous acid proves to be a better phosphorus doping agent than phosphoric acid since, in the PO₃³⁻ ion, the phosphorus already has a lower positive oxidation state than in the PO₄³⁻ ion whilst it has a negative oxidation number as doping agent in the silicon crystal. The phosphorus deposited on the surface 8 is driven into the emitter advantageously after the described processing of the surface layer 9 by a short-term high-temperature step.

Advantageously, in the present invention, the wetting behaviour and the viscosity of the component mixture can be influenced by the addition of surfactants and/or alcohols, above all by the addition of higher value alcohols, such as for example glycol or glycerine. Consequently, the etch notch form in the nitride 9 can be influenced.

A further variant according to the invention can be produced by the device represented in the Figure. This is based on a nozzle unit 1 which comprises a window 2 for coupling a laser beam 3 and also a liquid supply 4 and a nozzle opening 5. This nozzle unit serves to produce a liquid jet 6 into which the coupled laser beam 3 is guided by total reflection. The window 2 is orientated perpendicularly to a jet direction of the liquid jet 6. A precisely orientated lens 7 which is disposed above the window 2 serves to focus the laser beam. As liquid forming the liquid jet 6, a liquid which contains a doping agent is used, e.g. phosphoric acid. This is supplied to the nozzle unit 1 in a radial direction relative to the jet direction at a pressure of 20 to 500 bar by the liquid supply 4. This nozzle unit is directed towards a substrate surface of a silicon substrate 8. At the impingement point of the liquid jet 9, the result is doping of the surface region.

In addition, a metallisation can then be implemented in a further method step in that the phosphoric acid is exchanged for a silver cyanide or silver acetate solution and thus a thin silver layer of a few nanometres is grown on the doped region.

Two processing heads are used in succession for structuring+doping or metallising. In the first processing step, phosphoric acid is used as liquid together with a frequency-doubled Nd:YAG laser in order to achieve a local high doping with phosphorus. Subsequently, the second processing head contains a normal silver galvanic solution (e.g. silver cyanide-containing) with a frequency-doubled Nd:YAG laser. With this processing step, a thin silver layer of a few nanometres can be grown on the previously highly doped region which is thickened to a few micrometres in a subsequent electroplating step.

### EXAMPLE 1

### Nitride Structuring/Doping and Nucleation with a Solution Comprising Hypophosphite, Phosphoric Acid and a Metal Salt

In an embodiment of the present invention, all three chemical systems are combined from the three individual steps and their concentrations are adapted to the new system. Contrary to the concept is the fact that the interactions of the non-phosphorus-containing reagents from the individual process steps with each other are small. Thus metal ions for example in no way prevent the phosphorus glass formation and also not the etching effect of the phosphoric acid on the silicon nitride. Hydrogen phosphates and hypophosphite ions together form an effective redox pair which is able to reduce metal ions. The low pH value of the solution and the presence of hydrogen phosphate ions reduces the reduction potential of the hypophosphite, which initially is not undesired because the danger of spontaneous decomposition of the reaction bath, as arises in baths for current-free deposition of nickel, is consequently significantly reduced.

However, the hypophosphorous acid merely concerns a very weak acid with a very low boiling point. The low acid strength of the hypophosphorous acid does however ensure that the proton concentration is determined now almost exclusively by the phosphoric acid concentration in the solution which, for its part, must not finish up being too high because the reduction potential of the hypophosphite consequently drops too much in order to be able to reduce metal ions again. The concentration scope of the individual components is accordingly not unrestricted in such a system. The low boiling point of the hypophosphorous acid makes its capacity to be handled difficult in addition and increases the danger of a gradual concentration reduction in the system due to volatility of this component which is important for the complete system. Very high concentrations of hypophosphite in the solution reduce the durability of the liquid medium, which can present a significant problem for technical use. The chemical system proves accordingly to be extremely unstable with hypophosphite as reduction agent but absolutely very effective if a long durability of the solution is not required.

In the presented example, the following component systems inter alia can be used:

[NiCl₂.6H₂O]=0.1-1 mol/l

[NaH₂PO₂.H₂O]=0.1-5 mol/l

[H₃PO₄]=0.5-5 mol/l

Complexing agents for Ni²⁺ ions and buffers, e.g.: hydroxyacetic acid with: [HOCH₂COOH]=0.5-2 mol/l

### EXAMPLE 2

### Nitride Structuring/Doping and Nucleation with a Solution Comprising Phosphorous Acid, Phosphoric Acid and a Metal Salt

More stable against spontaneous decomposition are systems comprising phosphoric acid and phosphorous acid with water-soluble nickel salts as metal sources, e.g.: nickel chlorides NiCl₂.×H₂O, nickel sulphates NiSO₄.×H₂O or nickel nitrates Ni (NO₃)₂.×H₂O. The pH value of such systems is adjusted with the help of potassium hydroxide solution or even better ammonium hydroxide solution. As a rule, it is situated in the slightly acidic range.

HPO₃²⁻ ions comprising phosphorous acid and HPO₄²⁻ ions comprising phosphoric acid together form a redox pair. The second redox pair is formed by the nickel in the form Ni²⁺/Ni⁰:

HPO₃²⁻+3OH⁻⇄HPO₄²⁻+2H₂O+2e⁻ E°=1.12 V

Ni⇄Ni²⁺+2e⁻ E°=0.25 V

In basic media, the HPO₃²⁻ ion is, just like hypophosphite, a strong reduction agent, i.e. it is then also able to reduce ions of a few more base metals to the elementary metal, which however is not effected so spontaneously as with hypophosphite because of the lower reduction potential of the phosphite ion in which the phosphorus has the oxidation state +III relative to hypophosphite where it is +I. Spontaneous reduction of Ni²⁺ ions with phosphorous acid is scarcely noticed in aqueous solutions. On hot catalytically-acting surfaces, oxidation of the phosphite ion into phosphate, with reduction of metal ions, even those of nickel, is in contrast readily possible.

Phosphorous acid has in addition two further substantial advantages relative to hypophosphorous acid:
1) It has a significantly higher boiling point than hypophosphorous acid and therefore evaporates far less rapidly.
2) It is a substantially stronger acid and hence, similarly to phosphoric acid, is a more effective etching agent for the silicon nitride than hypophosphorous acid.

### Thermodynamic Promotion of the Redox Process for the Metal Deposition:

The reduction capacity (the electromotive force of the HPO₃²⁻/HPO₄²⁻ system) of an HPO₃²⁻ ion-containing solution is dependent upon the activities of the mentioned ions in the solution and upon the pH value of the solution, more precisely, of the hydroxide ion concentration. This is evident from the Nernst equation for the system HPO₃²⁻/HPO₄³:

$$Δ E ( {HPO}_{3}^{2 -} / {HPO}_{4}^{2 -} ) = - 1 , 12 V + \frac{0.059}{2} \cdot log \frac{a ( {HPO}_{4}^{2 -} )}{a ( {HPO}_{3}^{2 -} ) \cdot {a ( {OH}^{-} )}^{3}} V$$

In diluted solutions, the activity a of the individual species should be equated to the concentration c thereof of the respective species in the solution. The higher is the HPO₃²⁻ ion concentration and/or the higher the pH value, the more negative ΔE(HPO₃²⁻/HPO₄²⁻) becomes, i.e. the more the reduction capacity of the half-cell increases.

The EMF of a half-cell can however also be influenced via the temperature, evident from that of the general form of the Nernst equation:

$$Δ E = {E}^{∘} + \frac{RT}{zF} \cdot 1 g \frac{{a}_{Ox}}{{a}_{Red}}$$

with: ΔE=electromotive force (EMF); E°=normal potential (EMF under standard conditions); R=ideal gas constant=8.31451 JK⁻¹ mol⁻¹; T=absolute temperature in Kelvin; z=charge equivalent (number of exchanged electrons per formula unit); F=Faraday constant=96485 A×s; aₒₓ and a_{Red}=concentrations of the oxidised and the reduced species.

Accordingly, with increasing temperature, the reduction capacity of the half-cell also increases. The denominator of the logarithmic term of the Nernst equation is then larger relative to the numerator because the activity of the hydroxide ions has some influence on the numerator to the threefold power.

### Kinetic Promotion of the Redox Process for the Metal Deposition:

The acceleration of the reaction rate of a chemical reaction including therein also the redox reaction under consideration here is evident from the Arrhenius relation which describes the rate constant k of a reaction as a function of the temperature:

$$k = A \cdot {e}^{- \frac{{E}_{A}}{RT}}$$

with: k=rate constant, A=reaction-specific pre-exponential factor, EA=activation energy, R=general gas constant, T=absolute temperature in Kelvin

In the liquid light guide, the concentrations of the individual species are adapted to each other during the process such that, under standard conditions, in the given time window from the arrival of the solution until processing of the surface, they do not react with each other. For this purpose, the voltage between the redox systems Ni²⁺/Ni⁰ and HPO₃²⁻/HPO₄²⁻ must be kept sufficiently low, which can be effected via adjustment of the pH value or of the concentrations of participating species in the solution.

If now the solution is fired onto the silicon nitride surface which is heated and melted by the laser beam, then different processes thereby take place in succession:
1) Firstly, a part of the melt is removed from the melt by the high mechanical impulse of the liquid jet in that it is rinsed away from the latter. The melt which is removed in this way is subjected over a large active surface to the etching agent, phosphoric acid/phosphorous acid, and is dissolved by the latter so that it does not accumulate, as in the case of dry silicon nitride removal with lasers, on the edge of the cut notch. As a result, very clean cut grooves are produced.
2) As long as a silicon melt is present, the phosphorus sources present in the liquid jet can release the phosphorus contained therein to the silicon by means of purely thermal decomposition; the latter is to an extent melted into the silicon, likewise a part of the metal ions entrained with the liquid jet, in the present case, the nickel ions. In the molten silicon, the diffusion rate of the phosphorus is in addition very high. The incorporation of phosphorus is hereby effected all the better, the lower the oxidation state thereof because then all the fewer electrons require to be transferred from the system to the phosphorus which, as doping agent, is a more electron-negative bond partner in the silicon crystal relative to the silicon. By means of the mechanical impulse of the liquid jet, the doping and metallising mixture can be implanted properly into the silicon melt where it solidifies together with the melt, is consequently included and finally is incorporated in part directly in the silicon crystal. In this way, even with a single crossing of the cut notch, very high doping depths of several μm can be achieved optionally, as a function of the melt depth at the cut position. A further part of the chemical mixture remains included below the surface as phosphosilicate glass islands and can serve as further doping source for the silicon within the scope of a temperature-controlling step. The nickel which is likewise included locally in a very large quantity thereby alloys locally with the silicon to form Ni₂Si, as a result of which it contributes to reduction of the contact resistance.
3) Because of the high heat conductivity of the silicon, above all in the liquid state in which it has metallic properties, the temperature of the silicon declines relatively rapidly. A phosphosilicate glass thereby forms also on the silicon surface, the network former of which glass is a three-dimensional network comprising silicon and phosphorus atoms, which are connected to each other via oxygen bridges. A statistical part of the oxygen atoms has only one bond partner and a freely located valency with a negative charge. Ni²⁺ ions from the solution form the charge equalisation for this purpose and are consequently bonded electrostatically to the surface. During a further crossing step, they can diffuse from the phosphosilicate glass into the uppermost silicon layer and there form deposition nuclei for further nickel atoms. During the doping of the silicon with the help of phosphosilicate glass, phosphoric acid proves, in contrast, relative to phosphorous acid, to be the more favourable phosphorus source because therein all the valences of the phosphorus are saturated with oxygen atoms which are required for network formation in the glass.
4) In the course of the decline of the high temperatures on the silicon surface, that temperature region is also traversed at which only a thermal activation of the above-mentioned redox process between the phosphorous acid and the nickel ions is still effected in solution, but not direct melting of the components as at the beginning of the process. Now, thickening of the metal nucleation layer on the surface can take place as a result of the solution situated in the cut notch in that the above-portrayed redox reaction takes place locally on the nucleated and highly doped silicon surface.
   The phosphosilicate glass on the walls of the cut notch acts disadvantageously as insulator on the contact resistance of the solar cell, and for this reason it must be removed again in the course of the entire process after the doping has been effected. This can take place in parallel with the doping and nucleation process in that small quantities of hydrofluoric acid are added to the reaction mixture. In such cases, the thickening of the nuclei cannot then however be undertaken with one and the same solution which was used for the preceding process steps (nitride removal, doping, nucleation) because, in the presence of hydrofluoric acid, a pronounced tendency arises to renewed solution of the already deposited, elementary metal. Thickening of the contacts can be completed in such cases within the scope of a subsequent step in which, with the help of the LCE method, classic nickel solutions are introduced into the cut notches for current-free deposition of nickel and the cut notches are thereby locally heated with the help of the laser. The local deposition of the metal is thereby influenced by two factors:
   1. the high doping and already present nucleation of the groove walls which therefore act catalytically and
   2. the thermal or photochemical activation of the deposition process by the laser.

In the presented example, the following component systems inter alia can be used:

1) pH=6.5 [symbol] [OH⁻]=3.16×10⁻⁷ mol/l
[HPO₄²⁻]=5 mol/l
[HPO₃²⁻]=10⁻³ mol/l
[Ni²⁺]=5-7 mol/l

The voltage U between half-cells (Ni⁰∥Ni²⁺) and (HPO₃²⁻∥HPO₄²⁻) is then +0.205 V

2) pH=4 [symbol] [OH⁻]=10⁻¹⁰ mol/l
[HPO₄²⁻]=10⁻³ mol/l
[HPO₃²⁻]=6 mol/l
[Ni²⁺]=5 mol/l

The voltage U between the half-cells (Ni⁰∥Ni²⁺) and (HPO₃²⁻∥HPO₄²⁻) is here +0.12 V

3) pH=6 [symbol] [OH⁻]=10⁻⁸ mol/l
[HPO₄²⁻]=1 mol/l
[HPO₃²⁻]=5×10⁻² mol/l
[Ni²⁺]=1-5 mol/l

The voltage U between the half-cells (Ni⁰∥Ni²⁺) and (HPO₃²⁻∥HPO₄²⁻) is in this case +0.10 to +0.12 V

4) pH=5 [symbol] [OH⁻]=10⁻⁹ mol/l
[HPO₄²⁻]=1 mol/l
[HPO₃²⁻]=10⁻¹ mol/l
[Ni²⁺]=1-3 mol/l

The voltage U between the half-cells (Ni⁰∥Ni²⁺) and (HPO₃²⁻∥HPO₄²⁻) is here +0.04 V.

### EXAMPLE 3

### Nitride Structuring/Doping/Nucleation and Damage Etch with a Chemical System Comprising KOH Solution, Hydrogen Phosphate Salt and Metal Salt

According to the choice of laser wavelength, damage in the crystalline structure, during processing of the contact grooves, can be produced with a different penetration depth which is undesired because of their quality-reducing factor for the electrical properties of the solar cells. In the case of BC solar cells, this damage is removed again after preparing the grooves by an additional damage etching step, before the metallisation step is implemented.

In the present invention, this damage etch can be effected in parallel with the three partial processes: nitride opening/doping/nucleation in that the chemical system used for this purpose is adapted. At this point, reference may be made once again to the works of Baumann et al. 2006, in which it was revealed that, with the LCE method on the basis of KOH solutions, a damage-free removal of silicon is possible.

Starting from the assumption that the nitride removal can also be implemented extensively by a purely thermal ablation of the nitride and a metal nucleation of the doped silicon surface is conceivable also without reduction of the metal ions with the help of a phosphorus compound, the chemical systems presented in embodiments 1-2 can be modified such that the phosphorus-containing compounds are used exclusively for the phosphorus doping. In this context, a hydrogen phosphate salt, e.g. lithium hydrogen phosphate which is dissolved in a potassium hydroxide solution, serves as phosphorus source. The metal source is a nickel salt, e.g. nickel chloride. Because of the fact that, in the basic range, Ni(OH)₂ precipitates, a complexing agent for the nickel ions must also be added to the solution, e.g. ammonia, with which these form the [Ni(NH₃)₆]²⁺_{(aq)} complex which exists in basic media.

Doping and nucleation are effected here as described in embodiment 2 in points 1)-3). The damage etch is undertaken by potassium hydroxide ions which are located in the supernatant solution in the cut grooves during the process whilst liquid jet and laser beam proceed further. Lithium ions which, during the melting and solidifying process, are likewise incorporated in the silicon crystal locally at the contact points, reduce the contact resistance of the solar cell in addition.

The metal nucleation layer can, in a further process step, be thickened either by classic currentless nickel deposition or by other methods, for instance with the help of the Optomec® method.

In the presented example, the following component systems inter alia can be used:

content of the KOH solution: 2-20% by weight
[Li₂HPO₄]=0.1-5 mol/l
[Ni²⁺]=1 mol/l
approx. 20 ml conc. NH₃ solution/l solution

### EXAMPLE 4

### Nitride Structuring/Doping and Damage Etch without Metal Nucleation with Chemical Systems Comprising: Phosphoric Acid/Nitric Acid/Hydrofluoric Acid

If a metal nucleation is dispensed with in the course of the nitride structuring and simultaneous doping and this is implemented only in a subsequent step, then a mixture of HF/HNO₃ can be used as damage etch reagent which is added to the phosphoric acid. HF/HNO₃, relative to KOH, has the advantage as damage etch reagent of a much higher etching rate and isotropic etching properties.

In the presented example, the following component systems inter alia can be used:

content of phosphoric acid solution: 80-87% by weight
HF (49%): 35 ml/l solution
HNO₃ (70%): 15 ml/l solution

All the complete processes described here in the examples can be reduced of course by a simplified liquid jet composition to their partial processes. Thus for example a silicon nitride structuring can be effected with simultaneous doping also without metallisation if the metal salt is not added to the solution.

The above-described embodiments represent advantageous embodiments of the present invention. However, the invention is not restricted to these embodiments:
As indicated already, the method according to the invention can be used with the help of a combined liquid jet/laser beam 3, 6 or also merely with a laminar liquid jet 6 without coupling of laser light in order to remove the passivation layer 9 of the silicon. Hence, either the laser serves as initiator via its heating effect for the above-described chemical etching reaction or the liquid jet 6 effects this itself by its preceding heating before it is sent to the sample to be processed.
In addition to the reduction agent (phosphorous acid) indicated in the above examples, also other reduction agents can be used for metal ions. There are suitable in particular for this purpose sulphurous acid (H₂SO₃), nitrous acid (HNO₂) or also, from the field of organic chemistry, aldehydes (the latter are oxidised in the course of the described process then into carboxylic acids which in turn can develop simultaneously surfactant properties, which can be used for specific influencing of the wetting behaviour of the solutions on the nitride layer 9).
As an alternative to the mentioned phosphoric acid and phosphorous acid, also further acids of phosphorus or other acids can be used. Also the use of phosphorus-containing liquids, such as e.g. phosphoryl chloride (POCl₃) or phosphorus trichloride is possible.
Apart from passivation layers 9 of the silicon comprising silicon nitride, also other passivation layers, such as for example SiO₂ layers, can be processed in that the etching media composition is correspondingly adapted to the layers.
Instead of phosphorus, also compounds of other elements of the fifth main group of the periodic table can be used as doping agents. For example, nitrogen, arsenic or antimony compounds can be used. Also the use of doping agents from other main or subsidiary groups of the periodic table is possible.

With the device represented schematically in the Figure, an embodiment of the method according to the invention can be produced in which the laser beam 3 which is directed towards the surface layer 9 is guided for local heating of the surface layer 9 over the regions thereof to be removed before respectively the liquid jet 6 is guided over these regions. In addition, the aerosol jet can also be heated and consequently the surface layer 9 can be heated indirectly. For this purpose, the phosphoric acid contained in the liquid jet 6 and/or a gas contained in the aerosol jet can be pre-heated.

1. A method for precision processing of substrates comprising directing a liquid jet comprising a processing reagent towards a substrate surface and guiding the liquid jet over the regions of the substrate to be processed, wherein a laser beam is coupled into the liquid jet.

2. The method according to claim 1, wherein the substrate is selected from the group consisting of silicon, glass, metal, ceramic, plastic material and composites thereof.

3. The method according to claim 1, wherein the substrate on the surface to be treated comprises one or more coatings selected from the group SiNₓ, SiO₂, SiOₓ, MgF₂, TiO₂ and SiCₓ.

4. The method according to claim 1, wherein the liquid jet is laminar.

5. The method according to claim 1, wherein the laser beam is guided by total reflection in the liquid jet.

6. The method according to claim 1, wherein the liquid jet has a diameter of at most 500 μm.

7. The method according to claim 1, wherein the liquid is supplied in a radial direction relative to the jet direction.

8. The method according to claim 1, wherein the laser beam is actively adjusted in temporal and/or spatial pulse form selected from one or more of flat top form, M-profile or rectangular pulse.

9. The method according to claim 1, wherein, during the precision processing, an emitter diffusion of a doping agent into a silicon wafer as substrate is implemented.

10. The method according to claim 9, wherein the doping agent is selected from the group consisting of phosphorus, boron, indium, gallium and mixtures hereof.

11. The method according to claim 9, wherein the emitter diffusion is implemented with a liquid jet which comprises H₃PO₄, H₃PO₃ and/or POCl₃ and into which a laser beam is coupled.

12. The method according to claim 9, wherein parasitically deposited doping agents are removed again subsequently at the substrate edges.

13. The method according to claim 9, wherein doping of the substrate is effected merely in regions during the emitter diffusion.

14. The method according to claim 1, wherein, before the precision processing, at least one dielectric layer is deposited on the substrate for passivation.

15. The method according to claim 14, wherein the dielectric layer is selected from the group consisting of SiNₓ, SiO₂, SiOₓ, MgF₂, TiO₂ or SiCₓ.

16. The method according to claim 14, wherein microstructuring of the dielectric layer is effected during the precision processing.

17. The method according to claim 14, wherein the dielectric layer is opened by treatment with a dry laser or with a water jet-guided laser or a liquid jet-guided laser which contains an etching agent.

18. The method according to claim 14, wherein the dielectric layer is opened during treatment with the liquid jet-guided laser which comprises the processing reagent and the processing reagent is an etching agent which has a more strongly acting effect on the dielectric layer than on the substrate.

19. The method according to claim 14, wherein the dielectric layer is opened by treatment with the liquid jet-guided laser which comprises the processing reagent and the processing reagent is an etching agent with which damage in the substrate is re-etched.

20. The method according to claim 14, wherein the etching agent is selected from the group consisting of H₃PO₄, H₃PO₃, PCl₃, PCl₅, POCl₃, KOH, HF/HNO₃, chlorine compounds and sulphuric acid.

21. The method according to claim 16, wherein the microstructuring and the doping are implemented simultaneously.

22. The method according to claim 16, wherein, during the precision processing, doping of the microstructured silicon wafer is effected subsequent to the microstructuring and the processing reagent comprises a doping agent.

23. The method according to claim 16, wherein, during the precision processing, doping is produced only in regions in the substrate, subsequently liquid situated on the substrate surface is dried up and the substrate is treated thermally so that the substrate has a weak surface doping and a confined high local doping.

24. The method according to claim 21, wherein the doping agent is selected from the group consisting of phosphoric acid, phosphorous acid, solutions of phosphates and hydrogen phosphates, borax, boric acid, borates and perborates, boron compounds, gallium compounds and mixtures hereof.

25. The method according to claim 21, wherein the doping is implemented with a liquid jet-guided laser which contains the processing reagent.

26. The method according to claim 1, wherein, during the precision processing, application of a metal-containing nucleation layer on a silicon wafer is effected at least in regions.

27. The method according to claim 26, wherein the application is effected by nickel electroplating, nickel laser methods, ink jet methods, aerosol methods, vapour coating, laser sintering, screen printing and/or tampon printing.

28. The method according to claim 26, wherein the application of the nucleation layer is implemented with the liquid jet-guided laser which contains the processing reagent, the processing reagent containing at least one metal compound.

29. The method according to claim 28, wherein the at least one metal compound is selected from the group of compounds of silver, aluminium, nickel, titanium, molybdenum, tungsten and chromium.

30. The method according to claim 29, wherein the metal compound is silver cyanide or silver acetate.

31. The method according to claim 26, wherein, during the application of the nucleation layer, a metallisation is catalysed by the laser beam.

32. The method according to claim 26, wherein the nucleation layer is applied on the doped regions of the silicon wafer.

33. The method according to claim 26, wherein the microstructuring, the doping and the application of the nucleation layer are implemented in succession or in parallel.

34. The method according to claim 26, wherein, after application of the nucleation layer, a rear-side contacting, by vapour coating or sputtering, is applied.

35. The method according to claim 26, wherein, after application of the nucleation layer, an additional rear-side contacting is applied by laser-fired rear-side contacting (LFC).

36. The method according to claim 26, wherein, after application of the nucleation layer, a thermal treatment at temperatures of 100° C. to 900° C., is effected for 0.5 to 30 min.

37. The method according to claim 36, wherein the thermal treatment is effected by laser annealing with point or line focus.

38. The method according to claim 26, wherein, after the precision processing, thickening of the nucleation layer is effected subsequent to application of the nucleation layer.

39. The method according to claim 38, wherein the thickening of the nucleation layer is effected by galvanic deposition or by currentless deposition.

40. The method according to claim 16 for structuring a surface layer which is disposed on a substrate and consists of a first material, the substrate consists of a second material which is different from the first material, wherein the liquid jet which is directed towards the surface layer is guided over regions of the surface layer to be removed, the liquid jet comprising an etching liquid which has a more strongly etching effect on the first material than on the second material, and the surface layer is heated locally in advance or simultaneously in the regions to be removed.

41. The method according to claim 40, wherein the liquid jet comprises in addition a reduction agent.

42. The method according to claim 40, wherein the etching agent and the reduction agent comprise one and the same chemical element in different oxidation states.

43. The method according to claim 42, wherein the etching agent comprises H₃PO₄ and the reduction agent H₃PO₃ or the etching agent comprises H₂SO₄ and the reduction agent H₂SO₃ or the etching agent comprises HNO₃ and the reduction agent HNO₂.

44. The method according to claim 40, wherein the liquid jet comprises a phosphorus-containing liquid, comprising one or more of phosphoryl chloride and/or phosphorus trichloride.

45. The method according to claim 41, wherein the reduction agent is an aldehyde.

46. The method according to claim 41, wherein the liquid jet comprises, in addition to the etching liquid and the reduction agent, a metal salt, selected from a silver, nickel, aluminium or chromium salt.

47. The method according to claim 46, wherein the nickel salt is a nickel chloride NiCl₂, a nickel sulphate NiSO₄ or a nickel nitrate Ni(NO₃)₂.

48. The method according to claim 21 for local doping of solids in which at least one liquid jet which is directed towards the surface of the solid and comprises at least one doping agent is guided over the regions of the surface to be doped, the surface being heated locally in advance or simultaneously by a laser beam.

49. The method according to claim 1 wherein the precision processing comprises microstructuring, doping, deposition of a nucleation layer and thickening of the nucleation layer.

50. The method according to claim 49 wherein, during the precision processing, the method steps are implemented in succession or in parallel.

51. A device for implementation of the method according to claim 1 comprising a nozzle unit with a window for coupling a laser beam, a laser beam source, a liquid supply for a doping agent-containing liquid and a nozzle opening which is directed towards a surface of the solid.

52. The device according to claim 51, wherein the nozzle unit and the laser beam source is coupled to a guide device for controlled guidance of the nozzle unit over the surface to be doped.

53. The device according to claim 51, wherein the nozzle unit and the laser beam source are stationary and the solid is coupled to a guide device for controlled guidance of the solid relative to the nozzle unit and to the laser beam source.

54. A method of emitter diffusion of a silicon wafer according to claim 1.

55. A method of microstructuring a substrate according to claim 1.

56. A method of doping a substrate according to claim 1.

57. A method of applying a nucleation layer on a silicon wafer according to claim 1.
